(19) United States
(12) Patent Application Publication
(10) Pub. No.: US 2008/0290509 A1
(43) Pub. Date: Nov. 27, 2008

(54) Chip Scale Package and Method of Assembling the Same

(75) Inventors: Hien Boon Tan, Singapore (SG); Chuen Khiang Wang, Singapore (SG); Rahamat Bidin, Singapore (SG); Anthony Yi Sheng Sun, Singapore (SG); Desmond Yok Rue Chong, Singapore (SG); Ravi Kanth Kolan, Singapore (SG)

Correspondence Address: SUGHRUE MION, PLLC, 2100 PENNSYLVANIA AVENUE, N.W., SUITE 800, WASHINGTON, DC, 20037, US

(73) Assignee: UNITED TEST AND ASSEMBLY CENTER, Singapore (SG)

(21) Appl. No.: 10/581,395

(22) PCT Filed: Dec. 2, 2004
(86) PCT No.: PCT/IB2004/004394

§ 371 Date: Aug. 14, 2008

Related U.S. Application Data
(60) Provisional application No. 60/526,082, filed on Dec. 2, 2003.

(51) Int. Cl. H01L 23/488; H01L 21/60

(52) U.S. Cl. 257/737; 438/113; 257/E23.023; 257/E21.511

(57) ABSTRACT

A method of producing a chip scale package is disclosed. The method includes dicing a wafer into a plurality of chip arrays, each array including two or more integrated circuit chips. The method further includes mounting each array on a substrate and dicing each array, attached to the substrate, into individual chip scale packages, each individual chip scale package including only one integrated circuit chip.

This application claims the benefit of the co-pending U.S. Provisional Application No. 60/526,082 filed on Dec. 2, 2003, and incorporated herein by reference.

### BACKGROUND OF THE INVENTION

1. Field of the Invention

The present invention generally relates to the field of semiconductors. In particular, the present invention relates to an improved method of assembling a true Chip Scale Package (CSP).

2. Discussion of Related Art

Semiconductors are materials that have characteristics of insulators and conductors. In today's technology, semiconductor materials have become extremely important as the basis for transistors, diodes, and other solid-state devices. Semiconductors are usually made from germanium or silicon, but selenium and copper oxide, as well as other materials are also used. When properly made, semiconductors will conduct electricity in one direction better than they will in the other direction.

Semiconductor devices and integrated circuits (ICs) are made up of components such as transistors, and diodes, and elements such as resistors and capacitors linked together by conductive connections to form one or more functional circuits. Interconnects on an IC chip serve the same function as the wiring in a conventional circuit.

Wire bonding is a method used to attach very fine metal wire to semiconductor components in order to interconnect the components with each other or with package leads. One problem encountered with wire bonds is the parasitic inductance that arises, which is based on the size and length of the wire carrying electricity to the components. Wire bonds are also fragile and have limited current carrying capacity.

A flip chip is a leadless monolithic structure, containing circuit elements, which is designed to connect electrically and mechanically to a hybrid circuit. Such a connection may be, but is not limited to, a structure such as a plurality of bumps, which are covered with a conductive bonding agent and are formed on the front-side planar face of the flip chip. In one conventional flip chip mounting technique for integrated circuits, an IC chip is placed front face-down on a mounting base layer element (a substrate) and is connected to wire patterns on the base layer element using the bumps as electrical contacts and the conductive bonding agent as an adhesive. Because the flip chip mounting technique can bond a chip to a base layer element over a much shorter distance than wire bonding, an effect of parasitic inductance can be reduced. Also, the thicker bumps are less fragile than wires and can conduct greater amounts of current. Therefore, some flip chips can be mounted onto a circuit base layer element with limited or even no need for wire bonding, and flip-chip mounting is drawing increasing interest as a mounting technique for high-frequency integrated circuits.

Conventional methods of producing flip-chip packages, however, involve singulating an individual IC chip from a wafer and attaching the singulated IC chip to a substrate. Such individual processing of a single IC chip is highly inefficient in that it is both time-consuming and expensive. Another problem associated with the individual mounting of a singulated IC chip onto a substrate is the difficulty of balancing a single IC chip (e.g. IC chip 10) on a single, central row of bumps (e.g. bumps 5), as illustrated in FIG. 1. Therefore, the conventional mounting of an individual IC chip, as described above, requires the use of an IC chip having peripheral bumps or having a full matrix array of bumps.

### SUMMARY OF THE INVENTION

A method of producing a chip scale package according to an exemplary embodiment of the present invention comprises mounting all array of two or more IC chips on a substrate and dicing the array, attached to the substrate, into individual chip scale packages, each package including only one IC chip.

A method of producing a chip scale package according to another exemplary embodiment of the present invention comprises providing a wafer and dicing the wafer. The wafer comprises a plurality of IC chips and the wafer is diced into a plurality of chip arrays, each array comprising two or more IC chips. After dicing, each array is mounted on a substrate and then each array, attached to the substrate, is diced into individual chip scale packages, such that each package includes only one IC chip. Each array may comprise a 2×2, 3×3, or 4×4 matrix of IC chips.

A method of producing a chip scale package according to yet another exemplary embodiment of the present invention comprises providing a wafer and dicing the wafer. The wafer comprises a plurality of IC chips, each comprising a plurality of bond pads aligned on an upper surface of the IC chip and a plurality of conductive bumps formed on the plurality of bond pads. The wafer is diced into a plurality of chip arrays, each array comprising two or more IC chips. Each array is then dipped in flux material so that flux material adheres to the bumps on the IC chips of the array. Each array is then mounted on a substrate so that the bumps align with corresponding solder pad openings on an upper surface of the substrate, and so that the flux material adheres the bumps to the solder pad openings. Then, the IC chips of each array are reflowed, thereby melting the bumps and establishing a joint between the IC chips and the substrate. The IC chips, the bumps, and the substrate are then cleaned to remove residual flux material. Then, the IC chips are under fill encapsulated by injecting encapsulation material into a gap between the IC chips and the substrate. Solder balls are formed on the under surface of the substrate, conductively connected to the bumps. The array, attached to the substrate, is diced into individual chip scale packages, each package comprising only one IC chip.

### BRIEF DESCRIPTION OF THE DRAWINGS

These and other features, aspects, and advantages of the present invention will become better understood % with reference to the following description, amended claims, and accompanying drawings, which should not be read to limit the invention in any way, in which:

FIG. 1 is a perspective view of a conventional IC chip having a central row of bumps;

FIG. 2 is a perspective view of a conventional wafer;

FIG. 3 is a perspective view of a 2×2 array of IC chips, each having a central row of bumps, according to an exemplary aspect of the present invention;

FIG. 4 is a perspective view of a 2×2 array of IC chips, each having two central rows of bumps, according to an exemplary aspect of the present invention;

FIG. 5 is a perspective view of a 2×2 array of IC chips, each having a matrix of bumps, according to an exemplary aspect of the present invention;

FIG. 6 is a perspective view of an IC chip being mounted on a substrate according to an exemplary aspect of the present invention;

FIG. 7 is an enlarged perspective of a portion of the substrate of FIG. 6;

FIGS. 8, 9, and 10 are perspective views of steps of producing a chip scale package according to an exemplary aspect of the present invention;

FIG. 11 is a cross-section of a chip scale package according to an exemplary aspect of the present invention; and

FIG. 12 is another cross-section of a chip-scale package according to an exemplary aspect of the present invention.

FIG. 13 is a flow-chart of an exemplary method of the present invention.

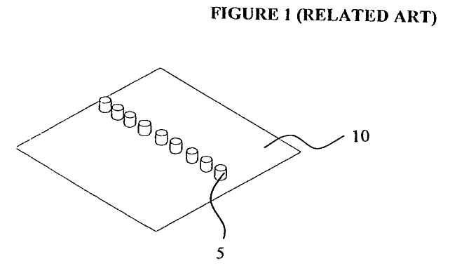

### DETAILED DESCRIPTION OF THE INVENTION

The present invention will be explained in further detail with reference to the accompanying drawings.

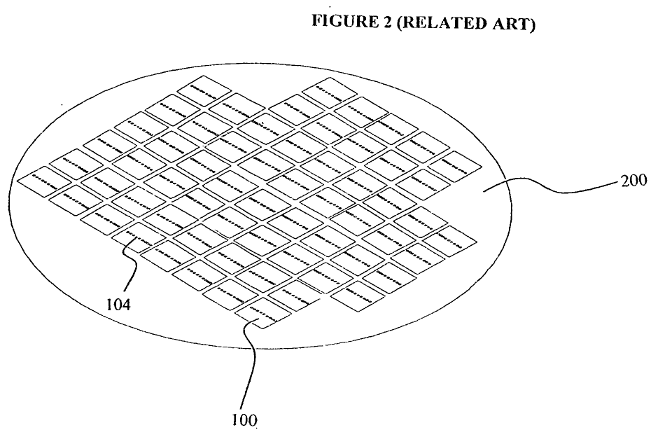

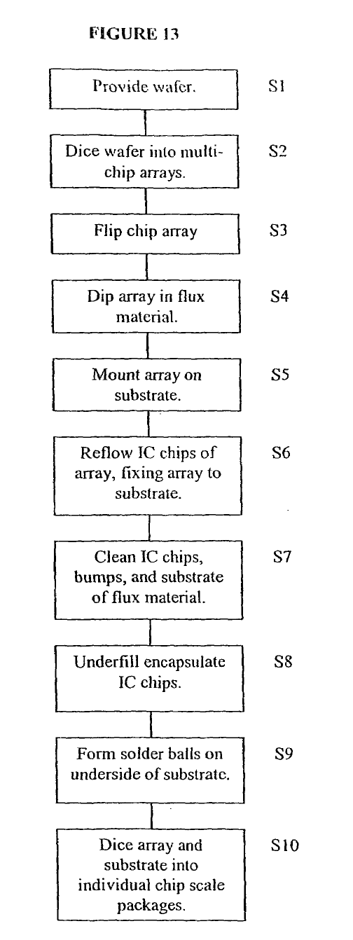

FIG. 2 is a perspective view of a conventional IC a wafer 200. The wafer 200 is provided in step S1 of an exemplary method according to the present invention, as illustrated in FIG. 13. As discussed, a typical IC wafer comprises a repeated pattern of IC chips 101, which can number into the thousands. For simplicity, FIG. 2 depicts only a small number the IC chips 101 which comprise the wafer 200.

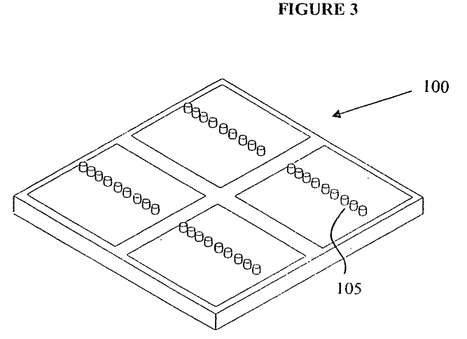

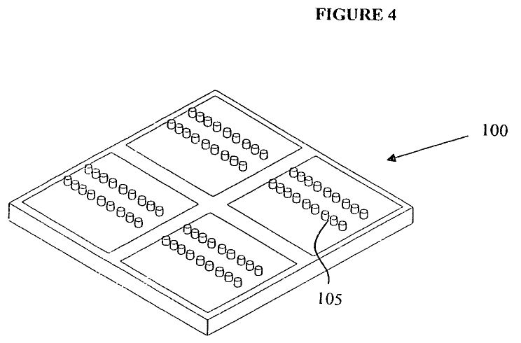

Each IC chip 101, includes a plurality of bond pads 104 formed on a top surface thereof. The bond pads 104 are applied through conventional printed circuit technology. A bump 105 (see e.g., FIG. 3) is formed on each of the bond pads 104 for the necessary standoff required in subsequent processing. As would be understood by one of skill in the art, the bond pads 104 and the bumps 105 may be aligned as a single row, as illustrated in FIG. 3. Alternatively, the bond pads 104 and bumps 105 may be aligned in two or more rows, as illustrated in FIG. 4. The two or more rows may be aligned at the center of the chip, as illustrated, or may be peripherally aligned at the edges of the chip. Further, the bond pads 104 and bumps 105 may be disposed in a matrix-like format over the whole surface of the chip, as illustrated in FIG. 5. The bumps 105 may be attached at a wafer bumping stage using electroplating or the chip may be solder printed and reflowed to form the bumps. The bumps 105 comprise a conductive material based on the requirements of the package. They mat comprise a eutectic alloy of lead/tin for standard packages or may be lead-free for green packages, as would be understood by one of skill in the art.

According to the present exemplary embodiment, a conventional IC wafer, such as wafer 200, is diced into separate chip arrays, (Step S2, FIG. 13). Each chip array comprises two or more IC chips. Each array may comprise a 2×2, 3×3, or 4×4 array of IC chips. However, the present invention is not limited to these specific arrays. The number of IC chips comprising an individual array is only limited by the requirements of the under fill encapsulation process (further described below), as would be understood by one of skill in the art. For simplicity, FIGS. 3 through 6 and 8 through 10 depict a 2×2 array 100, including IC chips 101A, 101B, 101C, and 101D. The preparation of chip arrays as described above enables multiple chips within an array to be handled as a single unit and processed together, as described below, rather than individually. This means that the processing is more efficient and less costly than processing chips individually.

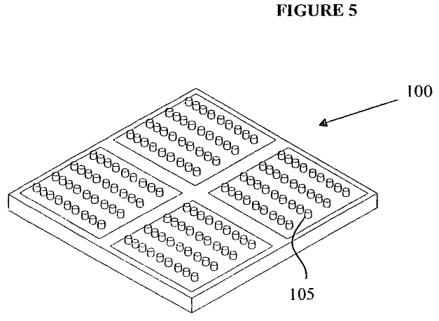

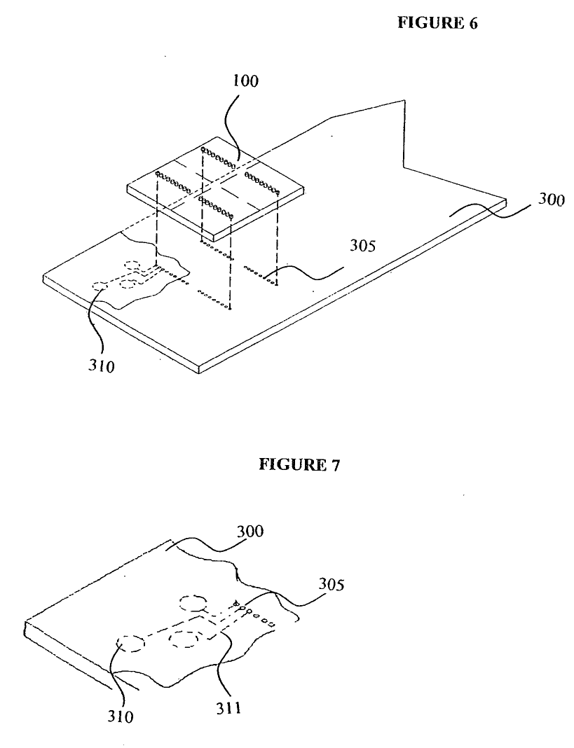

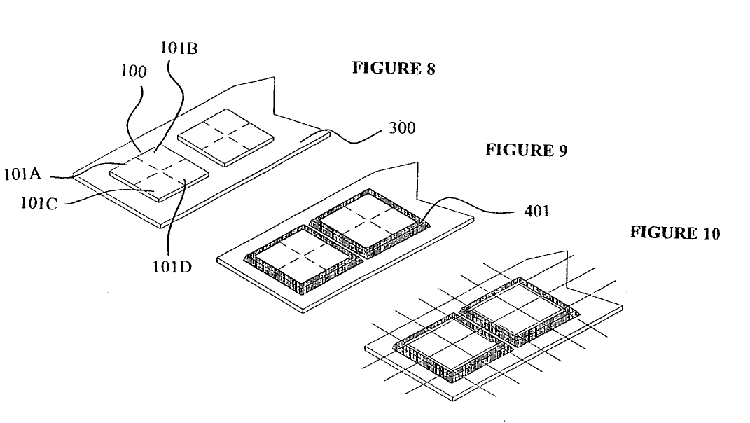

After a wafer is diced into chip arrays 100, each array, comprising multiple IC chips, is fixedly attached to a substrate 300, as illustrated in FIGS. 6 and 8. A plurality of chip arrays may be attached to a single substrate. The substrate 300 can have either a ceramic or organic composition, such as an epoxy-glass resin, or may comprise a variety of other materials as would be understood by one of skill in the art. Further, the substrate 300 may comprise a plurality of layers. As described below, the substrate 300 can later be coupled to a circuit board.

In order to attach the array 100 to the substrate 300, the array 100 is first flipped so that the bumps 105, disposed on the upper face of the IC chip can be mounted to the substrate 300 (Step S3, FIG. 13).

As shown in FIGS. 6 and 7, the substrate comprises solder pad openings 305 on an upper surface thereof. The solder pad openings 305 are conductively coupled through conductive vias 311 to a matrix array of input/outputs (I/Os) 310 disposed on the under surface of the substrate 300. When the array 100 is mounted on the substrate 300, the bumps 105 are conductively coupled to the solder pad openings 305. Thus, the substrate 300 acts as an interposer enabling the redistribution of the I/Os.

After the array 100 is flipped, the array 100 is dipped in a flux material such that some amount of the flux adheres to the bumps 105. (Step S4, FIG. 13). The flux agent may vary based on the composition of the bumps 105, for example whether standard bumps are used or whether lead-free bumps are used. The flux thickness is carefully adjusted during the process of attaching the array to the substrate 300, so that the required amount of flux adheres to the bumps 105. The flux adheres to the bumps 105 and to the solder pad openings 305 of the substrate thus enabling the array and the bumps to remain aligned with the solder pad openings.

Once the array 100 is mounted on the substrate 300 (Step S5, FIG. 13), the IC chips 101A, 101B, 101C, and 101D are reflowed, thus securing a permanent joint between the IC chips and the substrate 300. (Step S6, FIG. 13). Following the reflow, the entire arrangement, including the array of IC chips and the substrate are submitted to a flux cleaning, which removes any amount of flux which remained on the arrangement subsequent to the reflow. (Step S7, FIG. 13).

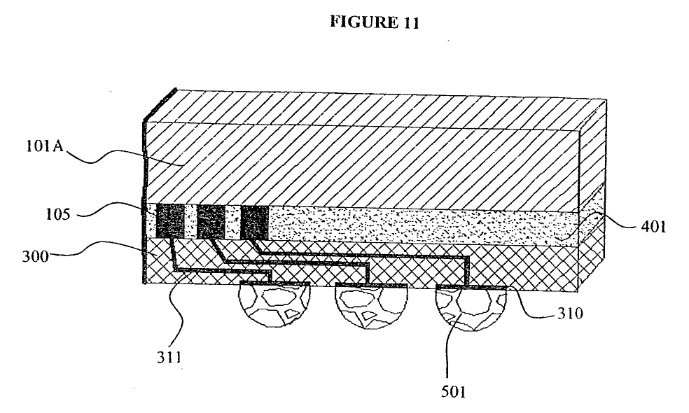

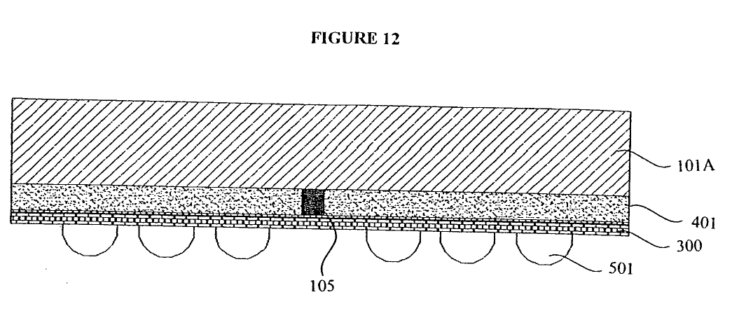

After the flux cleaning step, the IC chips 101A, 101B, 101C, and 101D of the array 100 are encapsulated, as shown in FIG. 9. (Step S8, FIG. 13). The under fill encapsulation process involves forcing an encapsulation material 401 into the gap between the IC chips 101A, 101B, 101C, and 101D and the substrate 300, around the plurality of bumps 105, as would be understood by one of skill in the art, and as shown in FIGS. 11 and 12. The back of the IC chip (facing upward in FIG. 9) remains free of any encapsulation material. The encapsulation material 401 can be a polymer-based molding compound or any other of many known encapsulation materials.

The under fill encapsulation material 401 strengthens the final package, helping to prevent shock or vibration from causing the electrical connections between the IC chips 101A, 101B, 101C, and 101D and the substrate 300 to sever. The under fill encapsulation also protects the connections from moisture and contamination.

The under fill encapsulation material 401 is dispensed at one or more sides of the gap between the IC chips 101A, 101B, 101C, and 101D and the substrate 300 and flows by capillary action until it fills the gap and surrounds each of the bumps 105. A low-viscosity under fill encapsulation material can be used to flow into the gap quickly enough to allow for high-speed production.

As an alternative to under fill encapsulation materials, and as would be understood by one of still in the art, a molding compound that is adapted to flow easily can be applied directly around the array 100 in FIG. 8. The molding compound can be, but is not limited to, a thermoplastic molding resin, a thermoset material which can be cured either by thermal or chemical activation, or any conventional molding compound.

Once the array 100 and the substrate 300 have been encapsulated, as described above, solder balls 501, as shown in FIGS. 11 and 12, are formed or mounted on the underside of the substrate over the I/Os 310. (Step S9, FIG. 13).

After the solder balls 501 have been formed on the under surface of the substrate, the entire arrangement is subjected to saw singulation, isolating each of the IC chips 101A, 101B, 101C, and 101D, as shown in FIG. 10. (Step S10, FIG. 13).

An exemplary individual true CSP, resultant from the above-described process, is illustrated in FIGS. 11 and 12. As shown, the bumps 105 provide a conducive connection between the IC chip 101A and the upper surface of the substrate 300. The encapsulation material 401 protects this connection and provides the CSP structure with needed support. Once the CSP is mounted on a circuit board (not shown), the bumps 105, the I/Os 310, connected through the substrate to the bumps 105 through the conductive vias 311, as discussed above, and the solder balls 501 provide the necessary conductive connection between the IC chip and the circuit board.

Although the above exemplary embodiments and aspects of the present invention have been described, it will be understood by those skilled in the art that the present invention should not be limited to the described exemplary embodiments, but that various changes and modifications can be made within the spirit and scope of the present invention.

What is claimed is:

1. A method of producing chip scale package, comprising:
attaching an array of two or more integrated circuit chips on a substrate;
dicing the array, attached to the substrate, into individual chip scale packages, each chip scale package comprising only one integrated circuit chip.

2. The method according to claim 1, wherein each of the two or more integrated c) circuit chips comprises:
a plurality of bond pads aligned in a single row and centrally disposed on an upper surface of the integrated circuit chip, and
a plurality of conductive bumps formed on the plurality of bond pads.

3. A method of producing a chip scale package, comprising:
providing a wafer, the wafer comprising a plurality of integrated circuit chips;
dicing the wafer into a plurality of chip arrays, each array comprising two or more integrated circuit chips;
attaching each chip array on a substrate;
dicing each array, attached to the substrate, into individual chip scale packages, each individual chip scale package comprising only one integrated circuit chip.

4. The method according to claim 3, wherein each chip array comprises one of a 2×2 matrix, a 3×3 matrix, or a 4×4 matrix of integrated circuit chips.

5. A method of producing a chip scale package, comprising:
providing a wafer, the wafer comprising a plurality of integrated circuit chips, each integrated circuit chip comprising
a plurality of bond pads aligned on an upper surface of the integrated circuit chip and
a plurality of conductive bumps formed on the plurality of bond pads;
dicing the wafer into a plurality of chip arrays, each array comprising two or more integrated circuit chips;
mounting each array on a substrate such that the bumps align with corresponding solder pad openings on an upper surface of the substrate;
reflowing the integrated circuit chips of each array, thereby melting the bumps and establishing a conductive joint between the integrated circuit chips and the substrate;
under fill encapsulating the integrated circuit chips and the substrate; and
dicing the array, joined to the substrate, into individual chip scale packages, each comprising only one integrated circuit chip.

6. The method according to claim 5, further comprising:
prior to mounting each array on a substrate, dipping each array in flux material, such that flux material adheres to the bumps;
wherein, when each array is mounted on a substrate, the flux material adheres the bumps to the solder pad openings.

7. The method according to claim 6, further comprising:
after reflowing the integrated circuit chips, cleaning the integrated circuit chips, the bumps, and the substrate to remove flux material.

8. The method according to claim 5, wherein:
under fill encapsulating the integrated circuit chips comprises injecting encapsulation materiel into a gap between the integrated circuit chips and the substrate.

9. The method according to claim 5, further comprising:
before dicing the array into individual chip scale packages, forming solder balls, conductively connected to the bumps, on the under surface of the substrate.

10. A multi-chip array package, comprising:
a substrate; and
a chip array, comprising two or more integrated circuit chips, flip-chip mounted on the substrate.

11. The multi-chip array package according to claim 10, wherein:
each of the two or more integrated circuit chips comprises a plurality of conductive bumps formed on an upper surface thereof; and
the chip array is mounted on the substrate such that the upper surface the two or more integrated circuit chips faces the substrate and the plurality of conductive bumps are conductively coupled to the substrate.

12. The multi-chip array package according to claim 11, further comprising:
encapsulation material disposed between the chip array and the substrate and around the plurality of conductive bumps.
